(19) United States
(12) Patent Application Publication
(10) Pub. No.: US 2025/0077742 A1
(43) Pub. Date: Mar. 6, 2025

(54) AUTOMATIC ENTITY EVALUATION AND SELECTION

(71) Applicant: SAP SE, Walldorf (DE)

(72) Inventors: Suresh PASUMARTHI, Bangalore (IN); Shiva Prasad NAYAK, Bangalore (IN); Venkata Phaneendra Kamal GUNUPUDI, Walldorf (DE); Venkata Kishore KEDARISETTY, Bangalore (IN)

(21) Appl. No.: 18/458,754

(22) Filed: Aug. 30, 2023

(51) Int. Cl. G06F 30/27; G06Q 30/0601

(52) U.S. Cl. CPC G06F 30/27; G06Q 30/0641

(57) ABSTRACT

According to some embodiments, systems and methods are provided including a memory, a processing unit and program code to: create an event, the event including an item value for a given quantity of an item provided by each of a plurality of entities; receive an event target; extract an entity identifier from the event target for each entity from the event; generate one or more simulations based on a plurality of characteristic parameter constraints and the event target; generate a characteristic parameter value for each of the plurality of characteristic parameters via execution of a machine learning model trained with prior values of characteristic parameters for the plurality of entities; scale the generated characteristic parameter values to a common unit of measure; generate an output, including a quantity distribution of the given quantity to at least one of the plurality of entities. Numerous other aspects are provided.

### BACKGROUND

Organizations often acquire goods and services in the operation of the organization. An organization may create a request for proposal (RFP) and hold an auction whereby multiple entities may be invited to propose terms associated with providing the goods and services as well as supply entity data, such as previous experience, acquired certifications, etc. After receiving the proposed terms and data, the organization may create a plurality of simulations including organizational constraints for selecting the entity. This may involve manually analyzing multiple steps for each simulation. Conventionally, in this highly manual selection process that requires significant effort by the organization, the organization may select an entity from the multiple entities based solely on two factors: the value of the proposed terms and the quantity that may be provided by the entity. It may be increasingly difficult for an organization to select an entity when there are multiple items that need to be procured for a given commodity, from multiple entities, some of who bid multiple times as there are multiple items at the auction, while keeping an organization strategy in mind.

Systems and methods are desired which make it easier to select an entity from multiple entities.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 is a high-level block diagram of a system according to some embodiments.

FIG. 2 is a flow diagram of a process according to some embodiments.

FIG. 3 is an outward view of a graphical user interface of event details according to some embodiments.

FIG. 4 is an outward view of a graphical user interface of item receipt details according to some embodiments.

FIG. 5 is an outward view of a graphical user interface of entity characteristics according to some embodiments.

FIG. 6A is an outward view of a graphical user interface of an entity recommendation with a first non-exhaustive example according to some embodiments.

FIG. 6B is an outward view of a graphical user interface of an entity recommendation according to some embodiments.

FIG. 7 is an outward view of a graphical user interface of an entity recommendation with a second non-exhaustive example according to some embodiments.

FIG. 8 is an outward view of a graphical user interface of an entity recommendation with the second non-exhaustive example and an output according to some embodiments.

FIG. 9 is an outward view of a graphical user interface of an entity recommendation with a third non-exhaustive example and an output according to some embodiments.

FIG. 10 is a block diagram of a custom NER model according to some embodiments.

FIG. 11 is a block diagram of a system for training of a machine learning model according to some embodiments.

FIG. 12 illustrates training of a machine learning model according to some embodiments.

FIG. 13 is a block diagram of cloud-based database deployment architecture according to some embodiments.

FIG. 14 is an outward view of a graphical user interface of an entity recommendation with a fourth non-exhaustive example and an output according to some embodiments.

Throughout the drawings and the detailed description, unless otherwise described, the same drawing reference numerals will be understood to refer to the same elements, features and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein. It should be appreciated that in development of any such actual implementation, as in any engineering or design project, numerous implementation-specific decisions must be made to achieve the developer's specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

One or more embodiments or elements thereof can be implemented in the form of a computer program product including a non-transitory computer readable storage medium with computer usable program code for performing the method steps indicated herein. Furthermore, one or more embodiments or elements thereof can be implemented in the form of a system (or apparatus) including a memory, and at least one processor that is coupled to the memory and operative to perform exemplary method steps. Yet further, in another aspect, one or more embodiments or elements thereof can be implemented in the form of means for carrying out one or more of the method steps described herein; the means can include (i) hardware module(s), (ii) software module(s) stored in a computer readable storage medium (or multiple such media) and implemented on a hardware processor, or (iii) a combination of (i) and (ii); any of (i)-(iii) implement the specific techniques set forth herein.

As described above, sourcing is an important aspect of supply chain management for an organization and may have a significant impact on an organization's costs, quality, availability of materials/products and branding of the organization. Organizations create requests for proposals (RFPs) and hold auctions for goods and services based on an organization's needs by inviting multiple entities to participate in the auction. The entities who participate in the auction often answer questions and provide a value for the good or service.

Conventionally, the organization manually creates various simulations with one or more steps using the entity data (e.g., answers and value) and organizational constraints to determine which entity to select. The conventional selection process often selects the entity based on the provided value and quantity offered. As a non-exhaustive example, the provided value may be a total cost offered to the organization for the item. However, often the total cost includes factors such as a transportation cost and a sales tax. These factors, as well as other factors like sustainability, regulations, supply chain continuity, diversity and quality, may be important considerations in selecting an entity. As more factors are considered, the complexity grows exponentially in selecting an entity and it may be difficult for an organization to manually compare the entities and evaluate the different factors to select an entity.

As a non-exhaustive example, consider a scenario where an organization needs 150 laptop keyboards. There may be three entities: Entity1 (E1) can provide 100 laptop keyboards for $85/laptop keyboard, Entity2 (E2) can provide 50 laptop keyboards for $92/laptop keyboard and Entity3 (E3) can provide 150 laptop keyboards at $95.Conventionally, the organization may create simulations for procuring the product at the different values. In a first simulation, the organization may procure 100 laptop keyboards from E1 and 50 laptops from E2 for a total value 13100 ((100*85)+(50*92)). In a second simulation, the organization may procure 150 laptop keyboards from E3 for a total value of 14250 (150*95). Solely based on value, the organization may select E1 and E2, as per conventional practice.

However, the organization may want to consider other factors in making their selection, including but not limited to quality, timeliness of delivery, etc. Keeping with the above non-exhaustive example, while E1 and E2 together may be provided at the lowest value, E1 may provide inferior products to E2 and E3, and the timeliness with which E2 provides the items is inferior to E1 and E3. It may be difficult for an organization to obtain this information and still even more difficult to analyze the information in a way that makes sense for the organization (e.g., one organization may value timeliness most, while another values quality most, and still another organization has a target saving of 20%). Also, the value may be based on the item itself. For example, timeliness may be more important for a perishable product like bananas than a non-perishable product like ore. As more factors are included in the analysis, the selection of an entity may become exponentially more difficult. Further, the above example is just for the laptop keyboard. However, the commodity the organization is sourcing for is a laptop, and there may be different items that may map to that laptop e.g., a mouse, a keyboard, etc. An individual RFP may be created for each item. The analysis may become more difficult as in some instances, a single entity may bid multiple times (e.g., providing a bid for a mouse and another bid for a keyboard).

Embodiments provide a selection module to address these problems. The selection module may create combinations of simulations, filter the simulations and select the final simulation and associated one or more entities to provide the item. In embodiments, prior to an event, the selection module may build a Name Entity Recognition (NER) model to parse an event target 128 (e.g., lowest value, etc.) from a user regarding an event (e.g., auction) and to extract key information. The event target 128 may be an organizational query in a plainly spoken language (e.g., English). Non-exhaustive examples of event targets may be: “at least 50% of total required for the item should be allocated to E1”; “Target saving of 20% based on a comparison of simulation 1 and simulation 2”. The selection module may also build an entity characteristics Artificial Intelligence (AI)/Machine Learning (ML) model. The selection module may access the AI/ML model when analyzing the different entities in response to the user event query to predict “desired entity characteristics”. The creation of an event may cause the selection module to retrieve desired entity characteristics (e.g., quality, timeliness, etc.) from the entity characteristics AI/ML model for the entities included in the event. The selection module may also receive an event target (e.g., lowest value, etc.), described above. Based on characteristic parameter constraints (e.g., importance assigned to each entity characteristic), event targets and extracted key information, the selection module may generate one or more simulations (e.g., E1+E2 vs E3). The different simulations may place a different importance/weight (co-efficient) on each of the characteristic parameters. Percentages may be assigned to each characteristic parameter to add up to 100%. For example, in a first simulation, the price characteristic parameter may have 34% importance, while each of the quality and timeliness characteristic parameters may have 33% importance. In a second simulation, the price characteristic parameter may have an 80% importance, the quality characteristic parameter may have a 15% importance and the timeliness characteristic parameter may have a 5% importance. The selection module also generates a characteristic parameter value for each characteristic parameter for a given item for a given entity. Continuing with the above non-exhaustive example where El has inferior quality to E2 and E3 for the quality parameter, E1 has a characteristic parameter value of 5, E2 has a characteristic parameter value of 6 and E3 has characteristic parameter value of 10, with 1 being bad and 10 being good. Next, one or more simulations are executed, and the selection module compares the simulations, taking the event target and the weighted characteristic parameter values into account, and outputs a recommendation for item distribution among the entities. Continuing the above non-exhaustive example, for a cost saving target, the selection module recommends distributing the 150 items to E2. As another example, for a different target, the selection module may recommend distributing the 150 items among more than one allotted entity, with 100 being allotted to E1 and 50 being allotted to E2.

The embodiments disclosed herein provide significant technical improvements to facilitate entity provisioning. The embodiments are directed to more than merely a computer implementation of a routine or conventional activity previously known in the industry. The embodiments provide improvement beyond a mere generic computer implementation as it provides: the automatic generation of simulations for many combinations and based on objectives; automatic assignment of co-efficient/weightage to different factors for a given commodity/item/category based on a target; provides for the parsing of an objective query via a prompt in free-form text; and based on historical data scales different entity characteristics. Embodiments simulate item distribution among entities and easily compare simulation outputs to provide a recommendation based on the assignment of importance of different factors. Embodiments also provide for the backward tracing of data on which the entity selection was based. In this way, it is easy for an organization to analyze how a distribution selection was made.

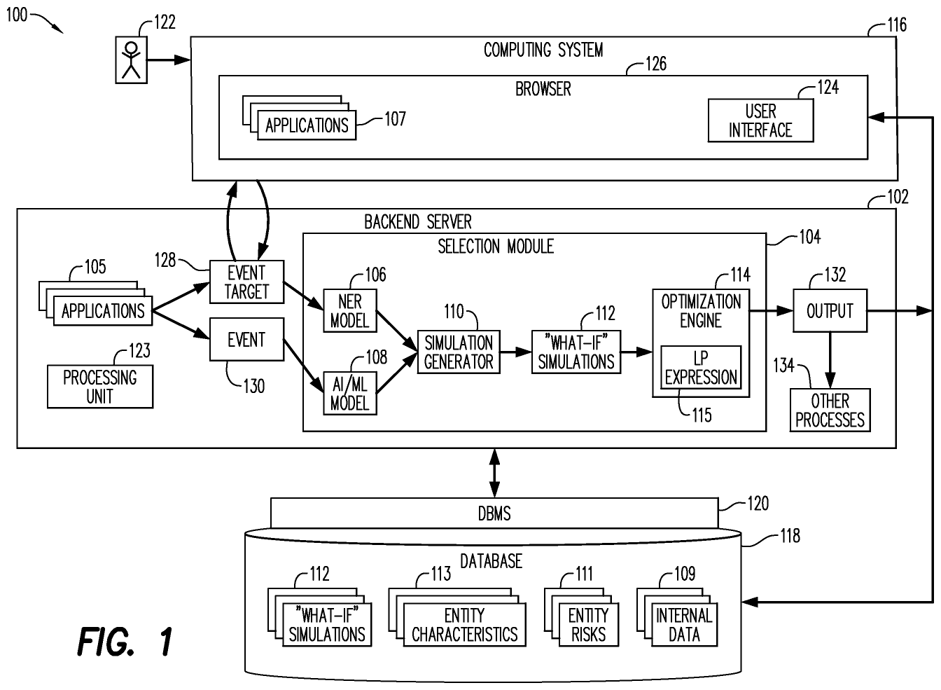

FIG. 1 is a block diagram of an architecture 100 according to some embodiments. The illustrated elements of architecture 100 and of all other architectures depicted herein may be implemented using any suitable combination of computing hardware and/or software that is or becomes known. Such combinations may include one or more programmable processors (microprocessors, central processing units, microprocessor cores, execution threads), one or more non-transitory electronic storage media, and processor-executable program code. In some embodiments, two or more elements of architecture 100 are implemented by a single computing device, and/or two or more elements of architecture 100 are co-located. One or more elements of architecture 100 may be implemented using cloud-based resources, and/or other systems which apportion computing resources elastically according to demand, need, price, and/or any other metric.

Architecture 100 includes a backend server 102 including a selection module 104, an application 105, a NER model 106, an Artificial Intelligence (AI)/Machine Learning (ML) model 108, a simulation generator 110, one or more “What-if” simulations 112, and an optimization engine 114. The architecture 100 also includes a local computing system 116, a database 118, a database management system (DBMS) 120, and a client/user 122. As used herein, the terms “client”, “user” and “end-user” may be used interchangeably.

The backend server 102 may include applications 105. Applications 105 may comprise server-side executable program code (e.g., compiled code, scripts, etc.) executing within the backend server 102 to receive queries/requests from clients 122, via the local computing system 116, and provide results to clients 122 based on the data of database 118. and the output of the selection module 104. A user 122 may access, via the local computing system 116, the selection module 104 executing within the server 102, to generate selection of at least one entity, as described below.

The server 102 may provide any suitable interfaces through which users 122 may communicate with the selection module 104 or application 105/107 executing thereon. The server 102 may include a Hyper Text Transfer Protocol (HTTP) interface supporting a transient request/response protocol over Transmission Control Protocol/Internet Protocol (TCP/IP), a WebSocket interface supporting non-transient full-duplex communications which implement the WebSocket protocol over a single TCP/IP connection, and/or an Open Data Protocol (OData) interface.

Local computing system 116 may comprise a computing system operated by local user 122. Local computing system 116 may comprise a laptop computer, a desktop computer, or a tablet computer, but embodiments are not limited thereto. Local computing system 116 may consist of any combination of computing hardware and software suitable to allow system 116 to execute program code to cause the system 116 to perform the functions described herein and to store such program code and associated data.

Generally, computing system 116 executes one or more of applications 107 to provide functionality to user 122. Applications 107 may comprise any software applications that are or become known, including but not limited to data analytics applications. As will be described below, applications 107 may comprise web applications which execute within a Graphical User Interface 124 and/or a web browser 126 of system 116 and interact with corresponding server applications 105 to provide desired functionality. User 122 may instruct system 116, as is known, to execute one the selection module 104. The user 122 may interact with resulting displayed user interfaces 124 output from the execution of applications, to analyze the selection and/or supporting data used to generate the selection.

The selection module 104 may include the NER model 106, the AI/ML model 108, the simulation generator 110, “What-if” simulations (“simulations”) 112 and the optimization engine 114.

The Name Entity Recognition (NER) model 106 may convert the query into an executable action by detecting and categorizing important information in text known as named entities. Named entities refer to the key subjects of a piece of text, including but not limited to names, locations, events, percentages, etc. The NER model 106 identifies, categorizes and extracts information from unstructured text (e.g., user query) without requiring time-consuming human analysis. The NER model 106 automates the extraction process and is able to quickly extract key information from large amounts of data. Pursuant to some embodiments, the NER model 106 may receive the query as a text file corresponding to the plain text of a human language (e.g., simple English) entered via a user interface, for example. The NER model 106 may convert the query from text format to a Java Script Object Notation (JSON) format. The conversion may be via any suitable converter. Based on the query, the NER model 106 may parse the text file to extract one or more tokens, and, from the tokens, the NER model 106 may extract keywords in the form of domain specific named entities based on pre-trained tagged tokens/named entities. It is noted that a conventional token extractor may only provide a token as a person, organization, geopolitical entity, currency, date, time, etc. However, it may be desirable to have an extractor that recognizes organizational context terms. To that end, the NER model 106 may be a domain specific NER model built according to embodiments, as described further below. The extracted data may include one or more entities, constraints and final selection criteria to select an entity for an item in a given event. The domain specific NER model 106 may be used to extract the event and identify the relevant entities and then the entities will become variables for the optimization engine 114, as described further below.

The AI/ML model 108 may be built on top of one or more computed entity characteristic data. The entity characteristic data may include internal data 109 (e.g., quality, timeliness, etc.) and external data (e.g., regulatory, environmental, operational and financial). The entity characteristic data may be based on historical procurement transactions including but not limited to purchase orders and receipts of the items. The AI/ML model 108 may also include entity risk data 111 in their analysis of an entity. Pursuant to some embodiments, the entity risk data 111 may be periodically provided by third-party data (e.g., from a third-party data source), via a push transaction to an analytics/reporting repository (preserving dimensions/facts/measure tables). The third-party entity risk data may include publicly available regulatory and legal data, environmental and social data, operational data and financial data. The third-party data source may be external data sources such as default entities, add-on licensed entities or public APIs. The Risk Data API (a public API) may include data from multiple custom fields across the four risk categories and a specific end point to bring in sanctions/watchlist screening results which may be available for the legal and regulatory risk category. The legal and regulatory data may provide information that describes entity activity that relates to the regulatory and compliance obligations that help to uphold and relate to lawful legal requirements (e.g., sanctions and watch lists bribery and corruption, legal, IT security, fraud, anti-competitive behavior, corporate crime). The environmental and social data provides information that describes entity behavior related to environmental protection, labor issues, ethical practices (e.g., human rights, labor issues, health and safety, environmental issues, conflict minerals, unethical practice, decertification, ethical practices, country risk). The environmental and social data may be helpful in protecting an organization's reputation when evaluating the practices of an entity. The operational data may provide information related to activity that will impact the day to day operations of the organization that may not be controlled by the entities (e.g., natural disasters and accidents, plant disruption or shutdown, labor issues, product issues, project delays, pandemic events). The financial data may provide information that may describe the actions that may affect the financial stability of the entities (e.g., bankruptcy, insolvency, mergers and acquisitions, divestiture, credit rating downgrade, downsizing liquidation, tax issue, financial data elements). These risk categories may be used to identify and aggregate risks identified by external data sources. The third-party entity risk data may segmented and classified for a given entity as “Unknown,” “Low”, “Medium” and “High” risks. The AI/ML model 108 may use this information to monitor the activity of the entity and ultimately determine an entity characteristic data value regarding the health of the entity.

After the AI/ML model 108 is built, a process 200, described further below, may retrieve desired entity characteristic data. According to embodiments, the selection module 104 may make use of two REST end point APIs: one to retrieve details about general entity characteristics for a given entity identifier; and one-in the form of an AI/ML inference API—to retrieve details about desired entity characteristics for a given entity identifier, item identifier and item value based on historical data. Based on event data 130, the AI/ML model 108 may use this entity characteristic data to predict “desired entity characteristics.” In particular, given the item value, an item identifier, a particular entity, and a risk classification for that entity, the AI/ML model 108 may generate an expected/predicted entity characteristic data value for quality, timeliness, etc. It is noted that the AI/ML model 108 may be updated with new and/or different entity characteristics.

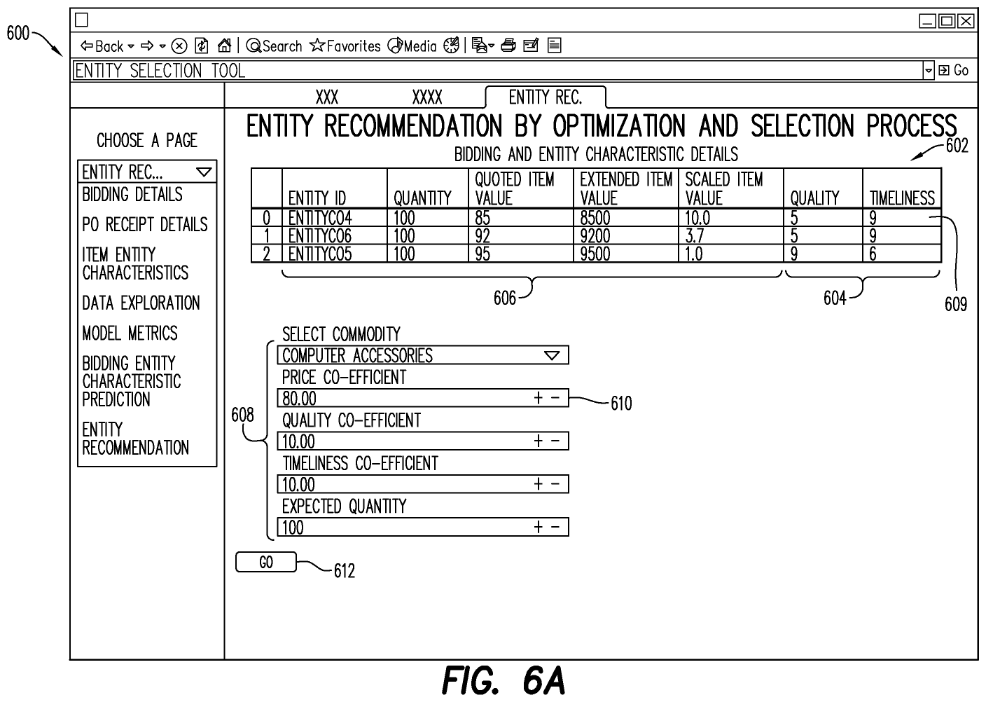

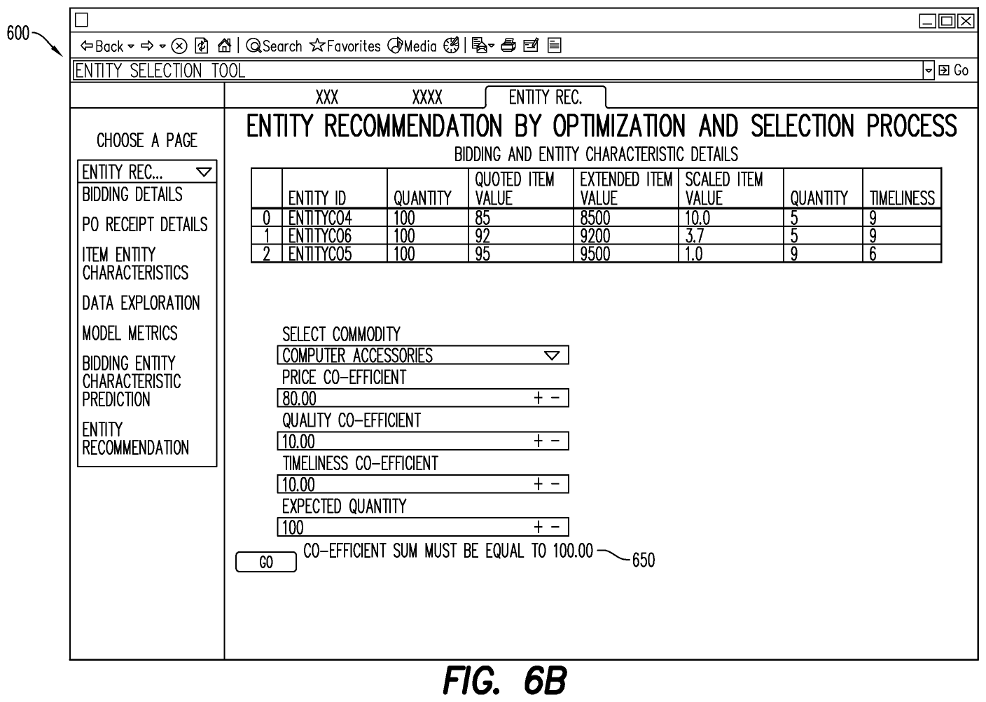

The simulation generator 110 may generate one or more simulations 112 based on desired entity characteristics predicted from the AI/ML model 108, a value for which may be predicted by the AI/ML model 108 and the tokens/named entities extracted by the NER model 106. For a given event target 128, the simulation generator 110 may create different simulations 112, keeping event data and entity characteristics the same, by varying the weight/co-efficient applied to each entity characteristic as described above. In some embodiments, the entity characteristic may be assigned a default weight/co-efficient based on the organization, the industry or other suitable basis. The user 122 may, in some embodiments, select different weights, as described further below with respect to FIGS. 6B-9. for the simulation generator to generate different simulations. The user may provide multiple co-efficient combinations for each entity characteristic and preserve them to perform further analysis for selecting entities. The simulation generator may also automatically change the weights to generate simulations based on the event target 128. The event target 128 may include one or more constraints associated with selecting the entity, including but not limited to, a minimum and maximum quantity entities can supply, a percentage of savings based on a comparison of multiple entities, and a range of values for an entity characteristic. As a non-exhaustive example, the quality may be between 20-30. Pursuant to some embodiments, the selection module 104 may be provided with “enriched entity data” along with the item value and answers to one or more questions supplied to the entities as part of the auction. The enriched entity data may be based on the item/commodity and a category region of the item for a given entity, and other suitable parameters. The enriched entity data may be received from internal and/or external sources. The external data may be related to operational, regulatory, environmental and financial elements (e.g., financial stability of entity). The internal data may be used to assign: a value to a quality of item, a value to the item, a timeliness value (e.g., delivery times), a customer service value, etc.

A historical purchase order for a given item may be a non-exhaustive example of internal data. The historical purchase order may supply entity data related to quality, delivery times, and the item value for the selected entity. The selection module 104 may use this data to generate scaled values for each parameter. Embodiments may provide a scaled value for the entity characteristic parameter so that the characteristics may be easily compared by the selection module 104. For example, quality may have a first unit of measure as total number rejected, while timeliness is a second, different unit of measure related to time (e.g., positive and negative numbers as related to delays and a timeline), and item value may be a third different unit of measure (e.g., decimals) as related to a monetary value.

The selection module 104 may determine a quality value to assign to a given entity based on historical items rejected. The percentage rejection=(1−((totalQuantity Received−totalRejectedQty/totalQuantityReceived)*100. The relation of the percentageRejected to given percentages may result in the assignment of a scaled quality value. As a non-exhaustive example, if percentageRejected is>80%, then Quality=1 . . . else percentageRejected<10%, Quality=10, wherein 1 and 10 are a scale with a Quality of 1 being the worst quality (e.g., more rejections) and a Quality of 10 being the best quality (e.g., less rejections). Other suitable percentages or thresholds may be used to assign the quality value. Like the timeliness value, the quality value may vary for perishable (e.g., bananas) versus non-perishable items (e.g., ore) and may be organization-determined. The value may be configurable per the organization, and the range may also be configured by the organization. For example, range of −28 to −20=10, range of −19 to −15=9, . . . , range of 0 to 3=1, where 1=Good and 10=Bad.

The selection module 104 may determine a delivery time (“timeliness”) value to assign to a given entity based on historical deviations from the promised delivery time. It is noted that “DiffDays” may refer to the difference in days of receipt of the item as compared to the required date. For example, a DiffDays measure of −2 means the item was received 2 days late. The negative values indicate the item was received late. The historical deviations may be measured as receiptDiffDays=NeedByDate (PurchaseOrder)−DateReceived. Then, as with the quality entity characteristic, the receiptDiffDays may be scaled. As a non-exhaustive example, if receiptDiffDays is less than or equal to −28, the

DeliveryTime/Timeliness value is 1 . . . and if receiptDiffDays is greater than −4.0 and less than −7.0, the Delivery Time/Timeliness value is 10, with a Delivery Time of 1 being the worst delivery timey (e.g., more delays) and a Delivery Time of 10 being the best delivery time (e.g., less delays). Other suitable percentages or thresholds may be used to assign the Delivery value.

The selection module 104 may also scale the item value of a given entity based on the entity identifier, the item/commodity and the item value itself, such that the scaled item value matches the scaled value of entity characteristics with respect to a common unit of measure. As above, the scale may be mapped with 1=bad and 10=good. Pursuant to some embodiments, the scaled item value may be referred to as “ScaledQuotedItem Value”.

The optimization engine 114 may generate a linear programming (LP) expression 115 for each simulation 112, based in part on the weight/co-efficient provided for the entity characteristics in each simulation. Then, the optimization engine 114 may evaluate each LP expression 115. There may be possible two outcomes for this evaluation (executed LP expression)-the LP expression is “feasible,” and the LP expression is “infeasible”. In the case the outcome of the executed LP expression is “feasible,” the one or more entities in that expression may be considered as a recommended entity. In the case the outcome of the executed LP expression 115 is “infeasible,” the optimization engine 114 may inject slack variables to the linear programming expression. As used herein, slack variables may refer to variables introduced to the linear constraints of the linear program to transform the constraints from inequality constraints to an equality equation. Then, all variables other than the slack variables are set equal to zero (e.g., if the inequality is 2x+3y ≤30, a slack variable “s” is added to fulfill 2x+3y+s−30=0). After adding the slack variable, if the equation is still infeasible (e.g., it cannot be converted to a feasible expression), then the expression is not further considered by the optimization engine 114 for output. The optimization engine 114 may then filter the feasible expressions by applying a “final selection criteria” provided as the event target 128 in the query to generate an output 132. The output 132 may contain details about the items and entities to supply the items. The output 132 may include a recommendation for quantity distribution of the given quantity in the request to at least one of the plurality of entities.

According to some embodiments, the selection module 104 may analyze additional variables in generating the output. The additional variables include, but are not limited to, contract variables (e.g., number of contracts from the entity, value of the contract, region-wise contract, deviation from terms (value data, quality), number of renewals, deviation from a standard template), entity variables (e.g., sustainability factors (carbon footprints, reusable), entity feedback, compliance, entity capacity, service, ratio of disputed invoices to total invoices, total difference between value paid and value quoted), other variables (compliance rate, entity defect rate, purchase order and invoice accuracy, rate of emergency purchases, entity lead time, purchase order cycle time, entity availability, cost per invoice and purchase order, spend under management, procurement return on investment and benefits, and value competitiveness).

Pursuant to embodiments, generation of the output 132 may trigger other processes 134. Non-exhaustive examples of other processes include the updating the machine learning model, and generation of operational contracts, purchase orders, receipts, billing and payments, etc. for the entities included in the output.

One or more applications 105/107 executing on backend server 102 or local computing system 116 may communicate with DBMS 120 using database management interfaces such as, but not limited to, Open Database Connectivity (ODBC) and Java Database Connectivity (JDBC) interfaces. These types of applications 105/107 may use Structured Query Language (SQL) to manage and query data stored in database 118.

DBMS 120 serves requests to store, retrieve and/or modify data of database 118, and also performs administrative and management functions. Such functions may include snapshot and backup management, indexing, optimization, garbage collection, and/or any other database functions that are or become known. DBMS 120 may also provide application logic, such as database procedures and/or calculations, according to some embodiments. This application logic may comprise scripts, functional libraries and/or compiled program code. DBMS 120 may comprise any query-responsive database system that is or becomes known, including but not limited to a structured-query language (i.e., SQL) relational database management system.

Backend server 102 may provide application services (e.g., via functional libraries) which applications 105/107 may use to manage and query the data of database 118. The application services can be used to expose the database data model, with its tables, hierarchies, views and database procedures, to clients. In addition to exposing the data model, backend server 102 may host system services such as a search service.

Database 118 may store data used by at least one of: applications 105/107 and the selection module 104. For example, database 118 may store the entity characteristic data 113 which may be accessed by the selection module 104 during execution thereof.

Database 118 may comprise any query-responsive data source or sources that are or become known, including but not limited to a structured-query language (SQL) relational database management system. Database 118 may comprise a relational database, a multi-dimensional database, an extensible Markup Language (XML) document, or any other data storage system storing structured and/or unstructured data. The data of database 118 may be distributed among several relational databases, dimensional databases, and/or other data sources. Embodiments are not limited to any number or types of data sources.

Presentation of a user interface as described herein may comprise any degree or type of rendering, depending on the type of user interface code generated by the backend server 102/local computing system 116.

For example, a client 122 may execute a Web Browser to request and receive a Web page (e.g., in HTML format) from a website application 105 of backend server 102 to provide the UI 124 via HTTP, HTTPS, and/or WebSocket, and may render and present the Web page according to known protocols.

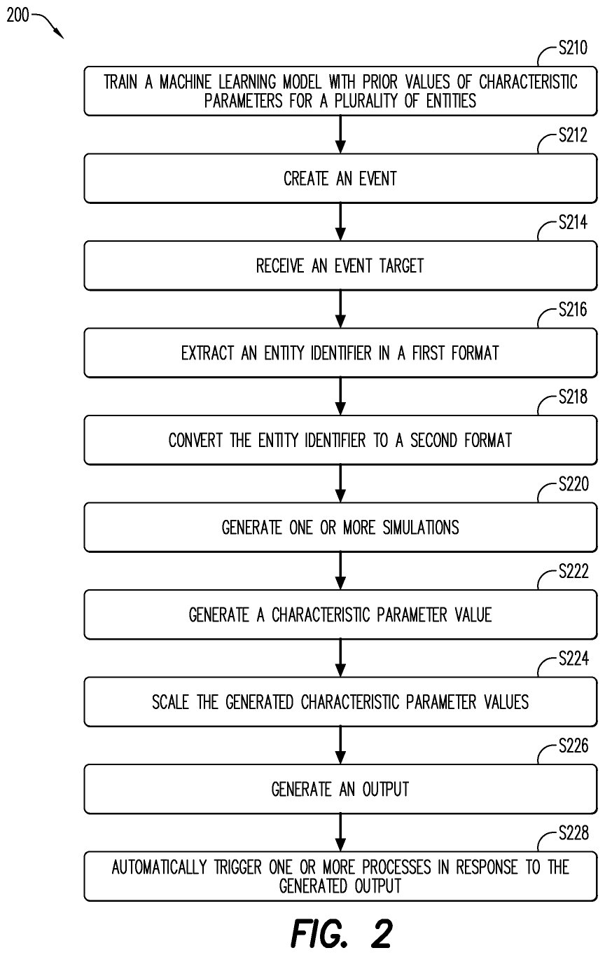

FIG. 2 illustrates a process 200 for selecting an entity in accordance with an example embodiment. For example, the process 200 may be performed by a database node, a cloud platform, a server, a computing system (user device), a combination of devices/nodes, or the like, according to some embodiments. In one or more embodiments, the computing system 116 or backend server 102 may be conditioned to perform the process 200 such that a processing unit 123 (FIG. 1) of the system 100 is a special purpose element configured to perform operations not performable by a general-purpose computer or device.

All processes mentioned herein may be executed by various hardware elements and/or embodied in processor-executable program code read from one or more of non-transitory computer-readable media, such as a hard drive, a floppy disk, a CD-ROM, a DVD-ROM, a Flash drive, Flash memory, a magnetic tape, and solid state Random Access Memory (RAM) or Read Only Memory (ROM) storage units, and then stored in a compressed, uncompiled and/or encrypted format. In some embodiments, hard-wired circuitry may be used in place of, or in combination with, program code for implementation of processes according to some embodiments. Embodiments are therefore not limited to any specific combination of hardware and software.

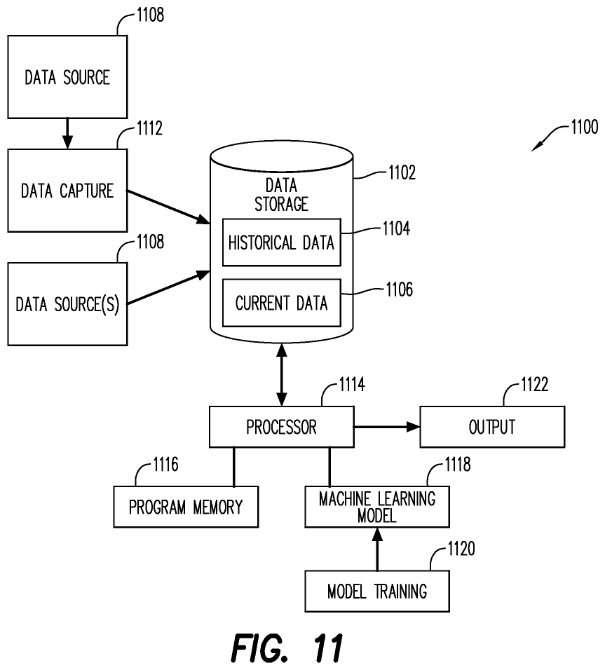

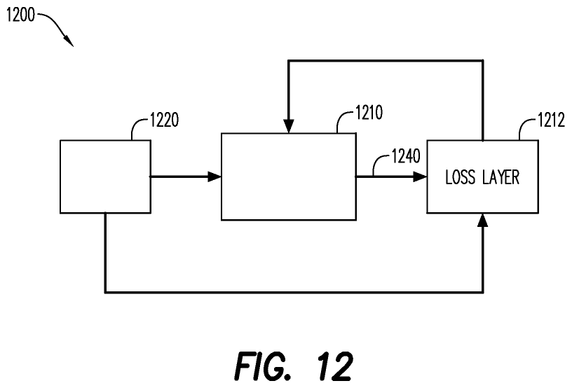

Initially, at S210, an AI/ML model 108 is trained with prior values of characteristic parameters for a plurality of entities. The training will be described further below with respect to FIGS. 11 and 12. According to one or more embodiments, a non-exhaustive example of an entity may be a provider of one or more items and/or services. The characteristic parameters may include, but are not limited to, quality, item value, timeliness, risk values.

Then, at S212, an event 130, is created. The event may be a request for proposals (RFP), whereby an organization invites entities to bid on providing goods and/or services needed by the organization. The RFP may include questions that may be answered by the invited entities. The questions may relate to previous experience, acquired certifications, and value of the item (“item value”) (good(s) and/or service) they will provide. The event 130 may include entity identifiers, the answers to the questions, including the item value for a given quantity of the item provided by each entity. The event data may be received in JSON format. In S214, an event target 128 is received at the NER model 106. The event target 128 may be an organizational query in a plainly spoken language (e.g., English) and in text format, which may be a first format. As described above, non-exhaustive examples of the event target 128 may be “Recommend Entity(s) subject to at least 50% of total required for item 1 is allocated to Entity1”; “Compare simulation 1 and simulation 2 and recommend entities based on a target saving of 20%”; “Recommend Entity by subject to the following constraints for itemgroup1 with a target saving of 20% and at least 50% of total required for item 1 should be allocated to Entity1.”

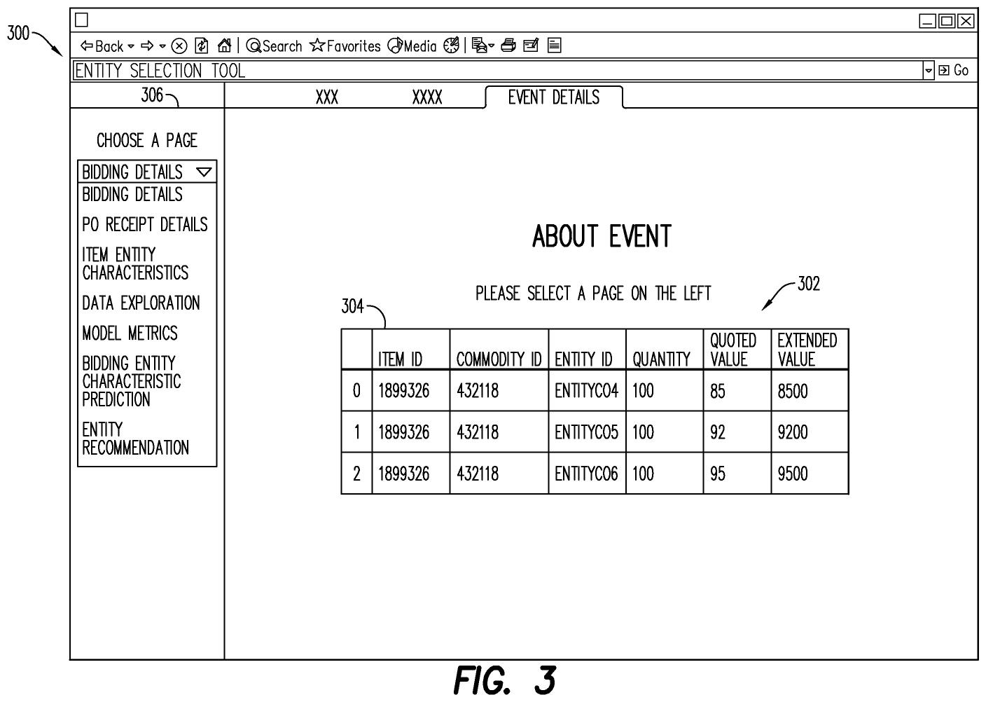

Pursuant to some embodiments, the event details may be displayed on a user interface. FIG. 3 is an example of an Event Details User Interface (UI) display 300 in accordance with some embodiments. The display 300 may be used by a user to view event data. The Event Details display 300 may include a table 302. The table 302 may include a plurality of parameters 304 related to the event, including, but not limited to, an itemID, a commodityID, an entityID, a quantity that may be provided by the entity, a quoted value and an extended value. As used herein, an Extended Value=Quantity*Quoted_Value. In this non-exhaustive example, we have three different entities providing data for a commodity including a particular item, and the organization requires a quantity of 100 of the item. EntityCO4 has a quoted value of 85 and an extended value of 8500 (100*85). As described above, the item may be internally mapped to the commodity in the database 118. The display 300 may also include a navigation panel 306 that may allow a user to navigate to another page. The other pages may include, but are not limited to, a Bidding Details page, a Purchase Order (PO) Receipt Details page, an Item Entity Characteristics page, a Data Exploration page, a Model Metrics page, a Bidding Entity Characteristic Prediction page, and an Entity Recommendation page. Selection of one of the pages in the navigation panel 306 may bring the user to the selected page.

Turning back to the process 200, in one or more embodiments, the NER model 106 may extract an entity identifier for each entity included in the event 130 in S216. Once the entity identifier is extracted it may be a tagged token. Then in S218, the extracted entity identifier in the first format (e.g., text) may be converted to a second format (e.g., JSON). The first format may be a text format or other suitable format. The conversion may be via any suitable converter.

The simulation generator 110 may generate one or more simulations 112 (“What-if” simulations) based on a plurality of characteristic parameter constraints for the converted extracted entity identifiers of the event target 128 in S220. As described above the characteristic parameters may include quality, timeliness and value. The constraints may refer to a co-efficient/weight applied to the characteristic parameter based on one of default values or organizational input (manual or pre-defined). For example, the quality characteristic parameter may have a constraint of 30%. The different simulations may have different characteristic parameter constraint values for a same event target 128. For example, Simulation 1 may have the quality characteristic parameter constraint as 30%, while Simulation 2 may have the quality characteristic parameter constraint as 50%.

The values for the characteristic parameters may be generated by the AI/ML model 108 for the item for each entity in S222. The generated values are then scaled in S224 to a common unit of measure. It is noted that in other embodiments, with respect to generating the characteristic parameter value, S220 may be executed after S222/S224.

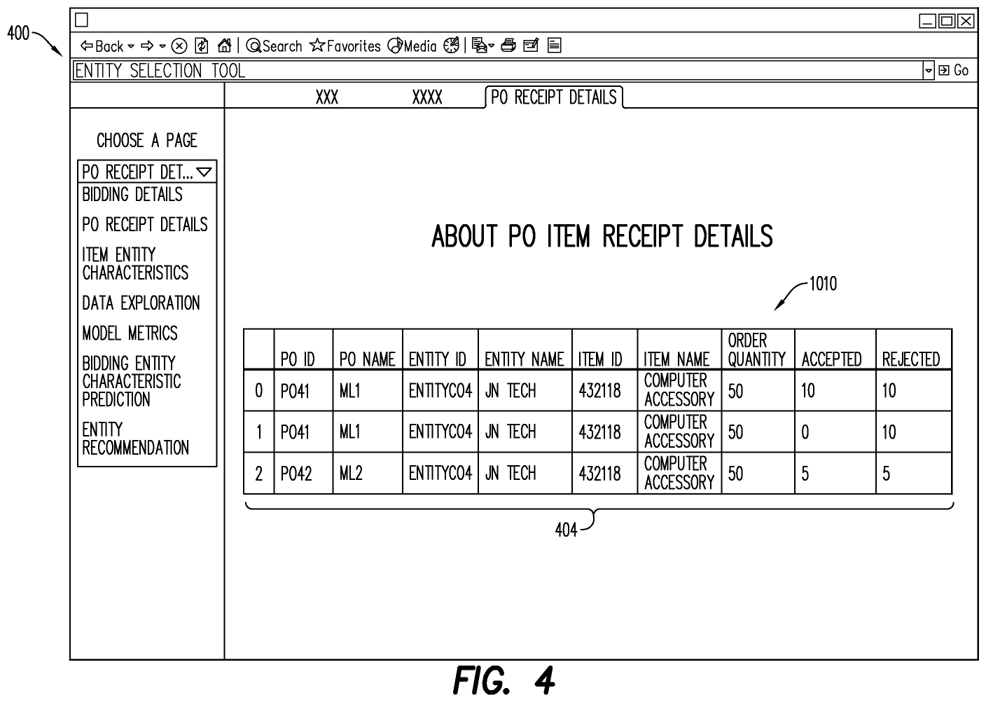

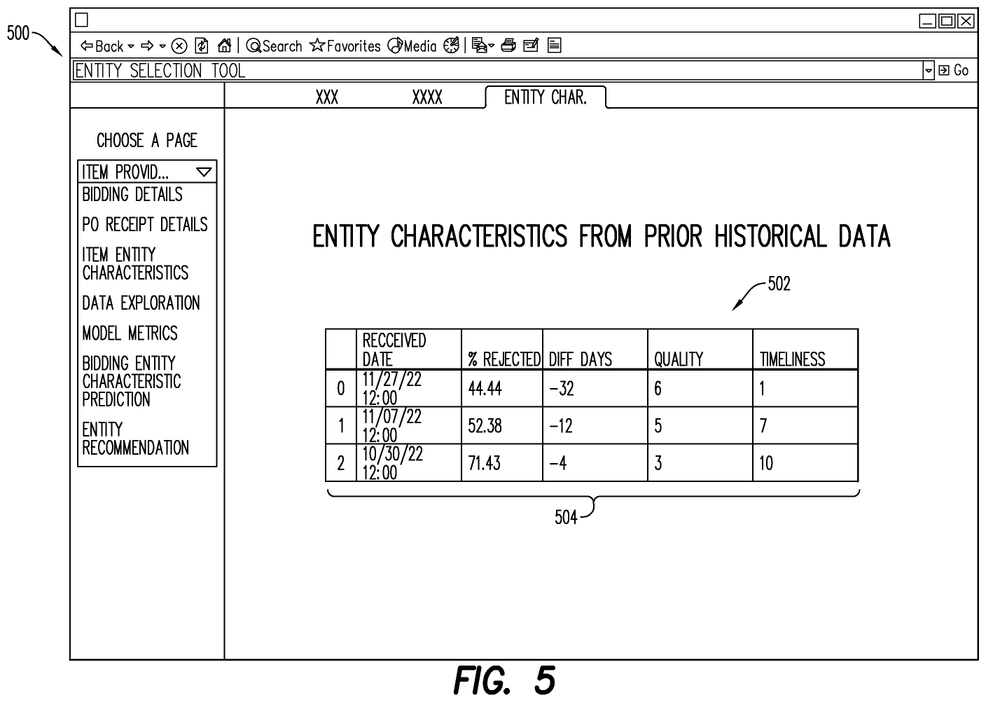

FIG. 4 provides an example of a Purchase Order Item Receipt Details user interface display 400 in accordance with some embodiments. The display 400 may include a table 402 providing the historical data 404 that may be used by the AI/ML model 108 to generate an expected entity characteristic data value for a quality value (FIG. 5). The historical data 404 may include a plurality of parameters including, but not limited to, Purchase Order Identifier (POId), Purchase Order Name (POName), Entity Identifier (ID), Entity Name, Item Identifier (ID), Item Name, Order Quantity, Accepted and Rejected. Looking at Row 0 for example, the order quantity is 50, accepted is 10 and rejected is 10. In some instances, some items may be rejected and then re-ordered and/or canceled from the order and then the entity will ship them again. After the back-and-forth the numbers should tally with the receipt. The AI/ML model 108 may compute the number of rejected items and accepted items at the receipt level, and then determine an acceptance rate and a rejection rate, as described below with respect to FIG. 5.

FIG. 5 provides an example of an Entity Characteristics from Prior Historical Data user interface display 500 in accordance with some embodiments. Continuing with the non-exhaustive example shown in FIG. 4, from the historical data 404, the entity characteristics may be computed by the AI/ML model 108. The Entity Characteristics from Prior Historical Data user interface display 500 may include a table 502 providing entity characteristic data 504. The entity characteristic data 504 may include a plurality of parameters including, but not limited to, a Received Date, a % Rejected, Difference of Days, Purchase Order (PO) Quality, PO Timeliness, Historical Quality, Historical Timeliness. The Percentage (%) Rejected may be calculated from the values in FIG. 4, as described above, and then scaled to generate the quality value. Similarly, the timeliness value is calculated from historical deviations from promised deviations values and scaled, as described above.

Turning back to the process 200, the selection module 104 may then generate an output 132 in S226. The output 132 may include a quantity distribution of a given quantity of the item to at least one of the plurality of entities. The output 132 may be generated via execution of the optimization engine 114. The optimization engine 114 may receive the scaled values for the characteristic parameters and generate one or more linear programming expressions 115 for each simulation 112 based in part on the co-efficient/weight provided by the given simulation. For the item value characteristic parameter, the LP expression is ScaledQuotedPrice*EntityID; for the quality value characteristic parameter, the LP expression is Quality*EntityID; and for the timeliness characteristic parameter, the LP expression is Timeliness*SupplierID. The optimization engine 114 may then evaluate each LP expression executed for each simulation and compare the outputs for each entity. As described above, the executed LP expression may be one of feasible or infeasible. In case the executed LP expression is infeasible, a slack variable may be injected to the expression to generate an updated LP expression, and the updated expression is re-executed. In case the re-executed LP expression is still infeasible, it is removed from consideration. The optimization engine 114 may then apply a filter to the feasible executed LP expressions by applying the event target 128 (“final selection criteria”). The optimization engine 114 may select the one or more simulations that include feasible executed LP expressions and optimally satisfy the event target as the output.

Next in S228, in response to the generated output, one or more other processes may be triggered. For example, the output including selection of item distribution among one or more entities may trigger other processes 134, including, but not limited to, creation of purchase orders, receipts, billing and payments with each respective system.

FIG. 6A provides an example of a Entity Recommendation by Optimization and Selection User Interface display 600 in accordance with some embodiments. The display 600 may be used by a user 122 to generate one or more simulations for a given event. A non-exhaustive example of a simulation 112 is provided in accordance with some embodiments. The display 600 includes a table 602 displaying the entity characteristics 604 (e.g., quality and timeliness) as generated by the AI/ML model 108 and event parameters 606 (e.g., quantity, quoted item value, extended value, and scaled item value) for each entity included in the event. The display 600 may also include a plurality of constraints 608 for the simulation. As described above, the simulations may be varied by applying different co-efficients/weights to the scaled values 609. The different co-efficients/weights may be constraints for the simulation. The display 600 includes a corresponding user entry field 610 for each constraint 609. In the non-exhaustive example shown herein, the user 122 has entered a co-efficient constraint of “80” for the Item Value Co-efficient, a co-efficient constraint of “20” for the Quality Value Co-efficient, a co-efficient constraint of “10” for the Timeliness Value Co-efficient. The user has also selected an Expected Quantity of 100 and “Computer Accessories” as the commodity. The display 600 also includes a “Go” icon 612.

Selection of the “Go” icon 612 may result in the Entity Recommendation by Optimization and Selection User Interface display 600 shown in FIG. 6B in accordance with some embodiments. In FIG. 6B, the display 600 includes an error message 650. The error message indicates the sum of the co-efficients must be “100”.

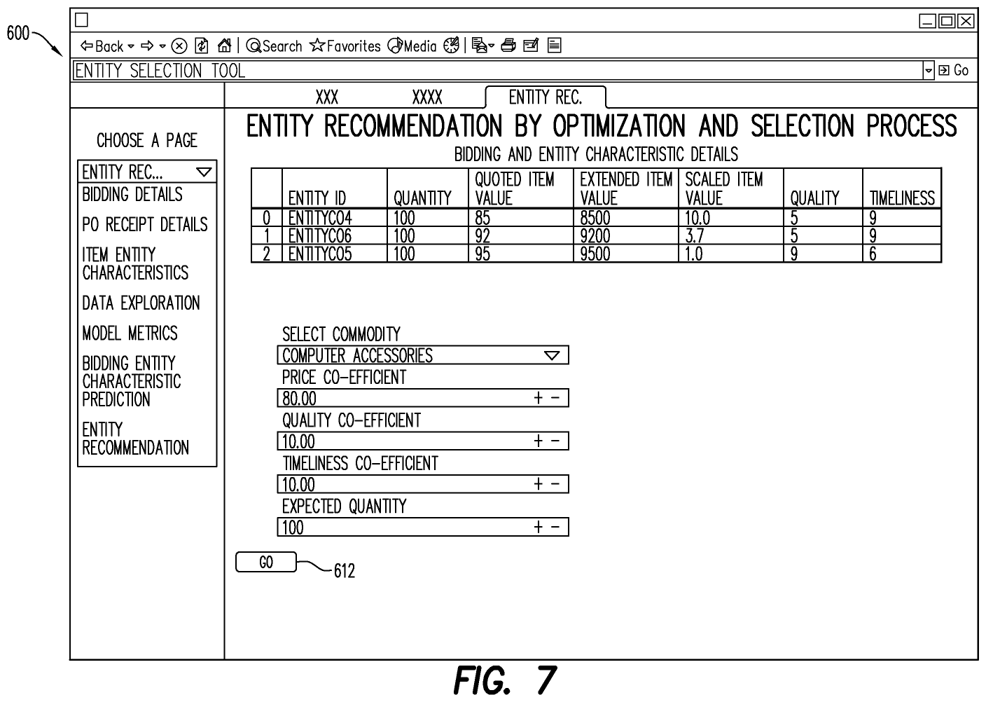

The user 122 may then change the co-efficients such that they sum to “100”, as shown in FIG. 7, where the user 122 has entered a co-efficient constraint of “80” for the Item Value Co-efficient, a co-efficient constraint of “10” for the Quality Value Co-efficient, and a co-efficient constraint of “10” for the Timeliness Value Co-efficient.

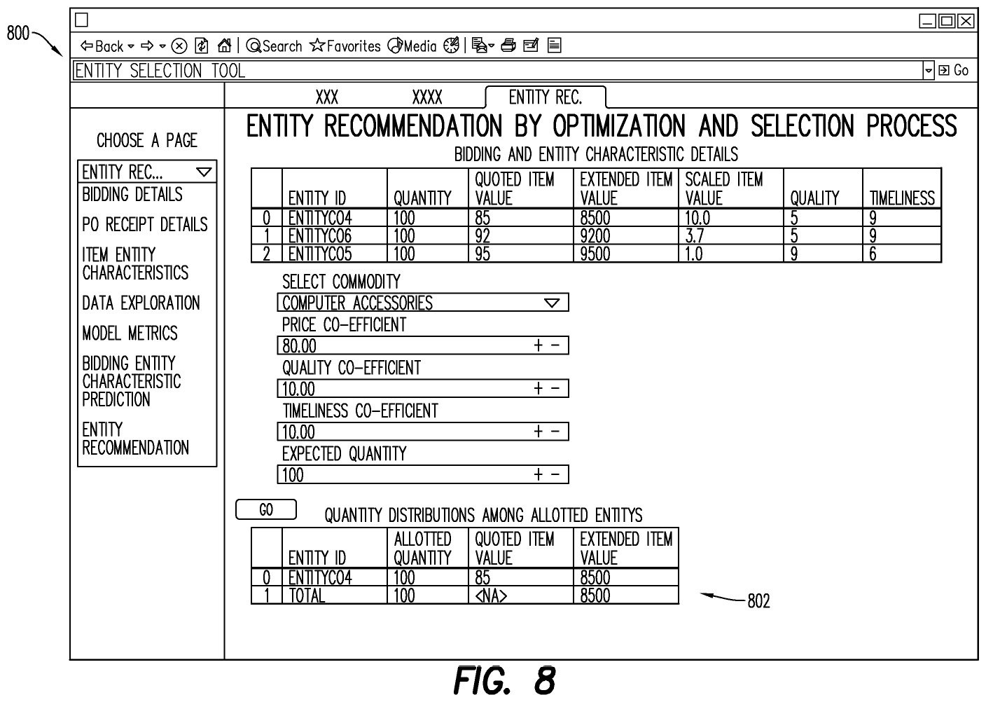

Selection of the “Go” icon 612 may execute the simulation and result in the Entity Recommendation by Optimization and Selection User Interface display 800 shown in FIG. 8 in accordance with some embodiments. The display 800 in FIG. 8 includes a table 802. The table 802 includes a recommended quantity distribution allotted among entities. In this non-exhaustive example, the optimization engine 114 recommends the entire expected quantity (100) be provided by EntityCO4.

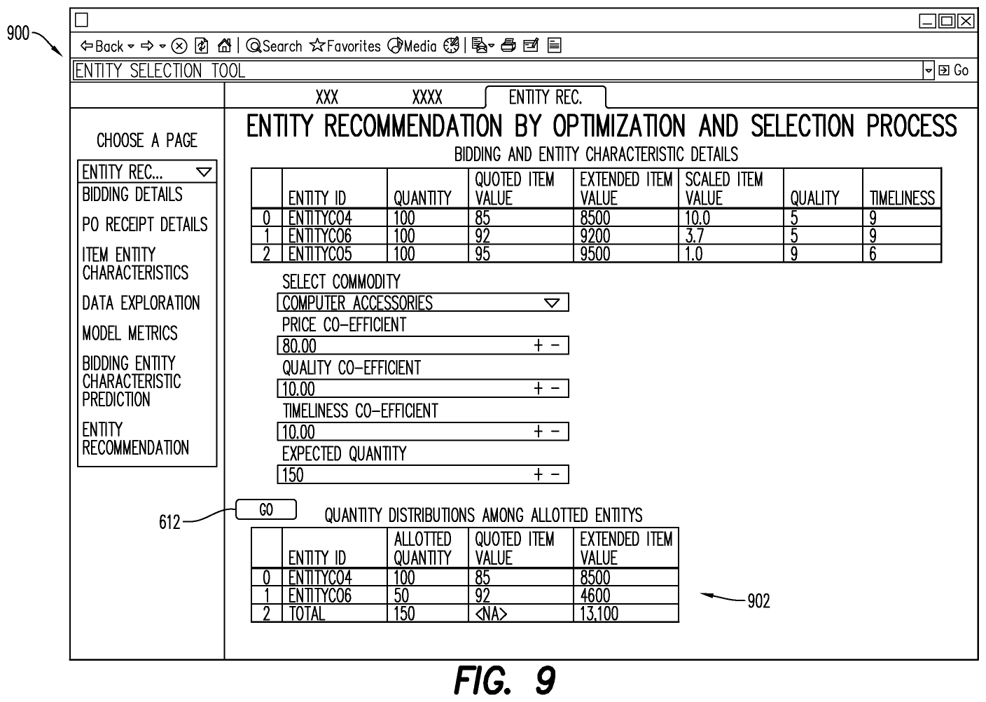

FIG. 9 provides the Entity Recommendation by Optimization and Selection User Interface display 900, as in FIG. 6A, with another non-exhaustive example. Here, the Expected Quantity is 150 (as compared to 100 in the non-exhaustive example shown in FIGS. 6A-8), such that the constraints expression, derived based on the event target, the following is SUBJECT TO: Constraint 1: EntityCO4+EntityCO5+EntityCO6=150. Given the weights/co-efficients price=80, quality=10 and timeliness=10, the price expression is: sum (Scaled_quoted_price(i)*entity_id(i))→10.0*EntityC04+1*EntityC05+3.7*EntityC06; the quality expression is: sum(quality(i)*entity_id[i])→5.0*EntityC04+9.0*EntityC05+5.0*EntityC06; and the timeliness expression is: sum(timeliness[i]*supplier_id[i])→9.0*EntityC04+6.0*EntityC05+9.0*EntityC06. The combined expression is: (weightage_price*priceExpression)+(weightage_quality*qualityExpression)+(weightage_timeliness*timelinessExpression)→(80*priceExpression)+(10*qualityExpression)+(10*timelinessExpression)→((80*10EntityCO4)+(80*1EntityCO5)+(80*3.7EntityCO6))+((10*5EntityCO4)+(10* (EntityCO5)+(10*5EntityCO6))+((10*9EntityCO4)+(10*6EntityCO5)+(10*9EntityCO6)→((800EntityCO4+80EntityCO5+296 EntityCO6)+(50EntityCO4+90EntityCO5+50EntityCO6)+(90EntityCO4+60EntityCO5+90EntityCO6)→sum for each entity→(800+50+90)EntityCO4+(80+90+60) EntityCO5+(296+50+90)EntityCO6>940EntityCO4+230EntityCO5+436EntityCO6. The entity optimization is to maximize 940.0*EntityC04+230.0*EntityC05+436.0*EntityC06, with variables for each of EntityC04, EntityC05 and EntityC06 being greater than or equal to 0 and less than or equal to 100.

Selection of the “Go” icon 612 executed the simulation and resulted in the table 902 shown herein, including a recommended quantity distribution allotted among entities. In this non-exhaustive example, the optimization engine 114 recommends the expected quantity be allotted among multiple entities. In particular the optimization engine 114 recommends EntityC04 provide 100 and EntityC06 provide 50.

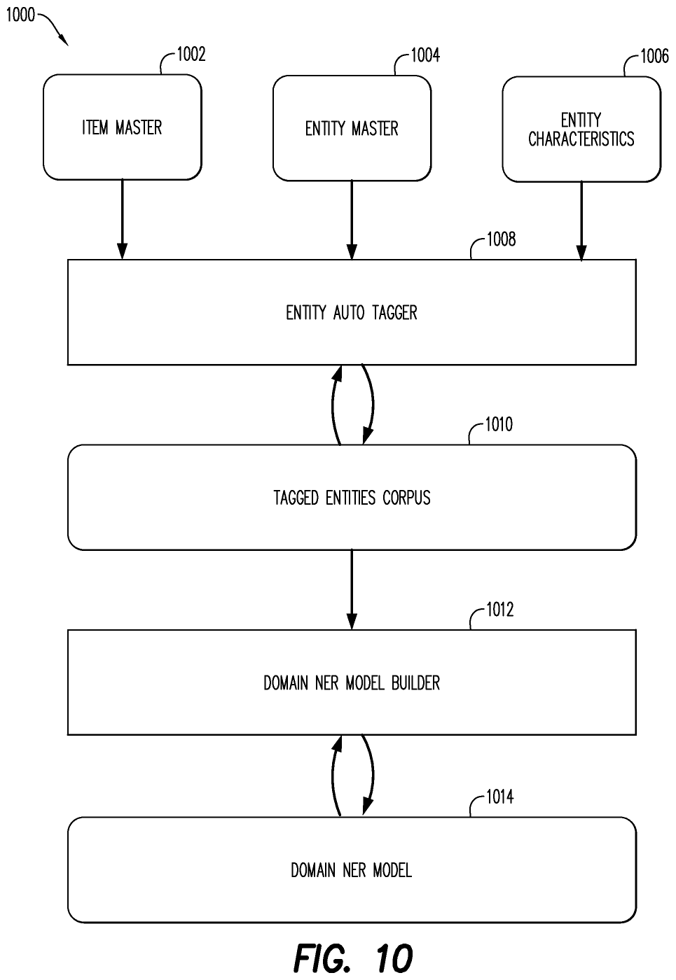

FIG. 10 is a block diagram 1000 of the architecture used in construction of the domain NER model 106. The architecture may include an item master database 1002, an entity master database 1004, and an entity characteristic database 1006. The item master database 1002 and the entity master database 1004 may include historical data. The item master database 1002 and the entity master database 1004 provide data related to items supplied by a given entity. For example, the item master database 1002 may include an item name, description and price; the entity master database 1004 may include an entity identifier, name address, etc., and the entity characteristic database 1006 may include quality, timeliness, etc., as described above. The data in each of the item master database 1002, entity master database 1004 and the entity characteristic database 1006 is structured data. The data from each of the item master database 1002, entity master database 1004 and the entity characteristic database 1006 is received at an entity auto tagger 1008. The entity auto tagger 1008 may identify and label with tags the named entities (Item Name, Entity Name, Entity characteristics). The tags may be words (e.g., “entity”, “item”) that represent a specific topic. The tagged entities may be stored in a tagged entity corpus 1010. A domain NER model builder 1012 may receive the tagged entities from the tagged entity corpus 1010 and use this data to build and train a domain specific NER model 1014. The domain NER model 1014 may be a domain specific customized model used to identify and extract from the relevant data (e.g., entity, item, etc.) from the query and then the extracted data may become variables for the optimization engine 114. Pursuant to some embodiments, each organization may have their own custom domain NER model with their own item master database and entity master database.

According to some embodiments, one or more machine learning algorithms and/or predictive models may be used to perform automatic entity characteristic valuation. Features of some embodiments associated with a model will now be described by referring to FIG. 11. FIG. 11 is a functional block diagram that illustrates aspects of a computer system 1100 provided in accordance with some embodiments of the invention.

The computer system 1100 includes a data storage module 1102. In terms of its hardware the data storage module 1102 may be conventional, and may be composed, for example, by one or more magnetic hard disk drives. A function performed by the data storage module 1102 in the computer system 1100 is to receive, store and provide access to both historical data 1104 and current data 1106. As described in more detail below, the historical data 1104 is employed to train a machine learning model to provide an output that indicates an identified entity performance metric, and the current data 1106 is thereafter analyzed by the model. Moreover, as time goes by, and results become known from processing current entity characteristics, at least some of the current decisions may be used to perform further training of the model. Consequently, the model may thereby adapt itself to changing conditions.

Either the historical data 1104 and/or the current data 1106 may include, according to some embodiments, entity characteristics with respect to quality, item value, timeliness, etc. The data may come from one or more data sources 1108 that are included in the computer system 1100 and are coupled to the data storage module 1102. Non-exhaustive examples of data sources may be the organization's purchase orders, entity documentation, external data sources, etc. It is noted that the data may originate from data sources whereby the data may be extracted from raw files or the like by one or more data capture modules 1112. The data capture module(s) 1112 may be included in the computer system 1100 and coupled directly or indirectly to the data storage module 1102. Pursuant to some embodiments, and as described above, an entity characteristic Application Programming Interface (API) may capture details about general entity characteristics for a given entity ID, an entity characteristic inference API may capture details about selected entity characteristics for a given entity ID, item id, item value based on historical data, and a Risk API may be exposed to capture risk-related data. Examples of the data source(s) 1108 that may be captured by a data capture model 1112 include data storage facilities for big data streams, document images, text files, and web pages. Examples of the data capture module(s) 1112 may include one or more optical character readers, a speech recognition device (i.e., speech-to-text conversion), a computer or computers programmed to perform NLP, a computer or computers programmed to identify and extract information from images or video, a computer or computers programmed to detect key words in text files, and a computer or computers programmed to detect indeterminate data regarding an employee such as a questionnaire response, etc.

The computer system 1100 also may include a computer processor 1114. The computer processor 1114 may include one or more conventional microprocessors and may operate to execute programmed instructions to provide functionality as described herein. Among other functions, the computer processor 1114 may store and retrieve historical purchase order, entity characteristics (from historical data) 1104 and current data 1106 in and from the data storage module 1102. Thus, the computer processor 1114 may be coupled to the data storage module 1102.

The computer system 1100 may further include a program memory 1116 that is coupled to the computer processor 1114. The program memory 1116 may include one or more fixed storage devices, such as one or more hard disk drives, and one or more volatile storage devices, such as RAM devices. The program memory 11116 may be at least partially integrated with the data storage module 1102. The program memory 1116 may store one or more application programs, an operating system, device drivers, etc., all of which may contain program instruction steps for execution by the computer processor 1114.

The computer system 1100 further includes a machine learning model component 1118. In certain practical embodiments of the computer system 1100, the machine learning model component 1118 may effectively be implemented via the computer processor 1114, one or more application programs stored in the program memory 1116, and computer stored as a result of training operations based on the historical data 1104 (and possibly also data received from a third party). In some embodiments, data arising from model training may be stored in the data storage module 1102, or in a separate computer store (not separately shown). A function of the machine learning model component 1118 may be to generate a metric regarding entity characteristics, etc. The machine learning model component may be directly or indirectly coupled to the data storage module 1102.

The machine learning model component 1118 may operate generally in accordance with conventional principles for machine learning models, except, as noted herein, for at least some of the types of data to which the machine learning model component is applied. Those who are skilled in the art are generally familiar with programming of predictive/machine learning models. It is within the abilities of those who are skilled in the art, if guided by the teachings of this disclosure, to program a predictive/machine learning model to operate as described herein.

Still further, the computer system 1100 includes a model training component 1120. The model training component 1120 may be coupled to the computer processor 1114 (directly or indirectly) and may have the function of training the machine learning model component 1118 based on the historical data 1104 and/or information about entities. (As will be understood from previous discussion, the model training component 1120 may further train the machine learning model component 1118 as further relevant data becomes available.) The model training component 1120 may be embodied at least in part by the computer processor 1114 and one or more application programs stored in the program memory 1116. Thus, the training of the machine learning model component 1118 by the model training component 1120 may occur in accordance with program instructions stored in the program memory 1116 and executed by the computer processor 1114.

In addition, the computer system 1100 may include an output device 1122. The output device 1122 may be coupled to the computer processor 1114. A function of the output device 1122 may be to provide an output that is indicative of (as determined by the trained machine learning model component 1118) particular metrics for an entity, etc. The output may be generated by the computer processor 1114 in accordance with program instructions stored in the program memory 1116 and executed by the computer processor 1114. More specifically, the output may be generated by the computer processor 1114 in response to applying the data for the current event to the trained machine learning model component 1118. The output may, for example, be a defined set of metrics for a given entity ID with respect to quality, timeliness and item value, etc. In some embodiments, the output device may be implemented by a suitable program or program module executed by the computer processor 1114 in response to operation of the machine learning model component 1118.

Further to the system 1100 of FIG. 11, described above, FIG. 12 also illustrates a system 1200 for training the Machine Learning (ML) model 1210, to generate entity metrics according to some embodiments. The training is based on the data input to the model 1210. Model 1210, and all other machine learning models described herein, may comprise a network of neurons (e.g., a neural network) which receive input, change internal state according to that input, and produce output depending on the input and internal state. The output of certain neurons is connected to the input of other neurons to form a directed and weighted graph. The weights as well as the functions that compute the internal state can be modified by a training process based on ground truth data.

Embodiments may comprise any one or more types of models that are or become known, including but not limited to convolutional neural network models, recurrent neural network models, long short-term memory network models, deep reservoir computing and deep echo state network models, deep belief network models, and deep stacking network models. Use of a multilayer model allows for complex non-linear relationships between input parameters and output probabilities.

As is known in the art, the structure of model 1210 is defined by hyperparameters and initial node weights. The hyperparameters and initial node weights are designed to receive a numerical representation of values for various parameters, and output a probability that the entity has particular entity characteristics. As shown in FIG. 12, model 1210 is trained based on data 1220. Data 1220 may consist of input parameter values for entity characteristic metrics, as described above. The detected entity characteristic values may be considered “ground truth” data corresponding to a respective one of the input values/performance KPIs.

Training of model 1210 may consist of inputting data 1220 to model 1210, and operating model 1210 to generate, for each input, prediction of an entity characteristic 1240. Loss layer 1212 determines a total loss based on a difference between the predictions 1240 and actual detected entity characteristics in the data 1220. The total loss is back-propagated to model 1210 in order to modify parameters of model 1210 (e.g., using known stochastic gradient descent algorithms) in an attempt to minimize the total loss.

Model 1210 is iteratively modified in the above manner, using a new batch of data 1220 at each iteration, until the total loss reaches acceptable levels or training otherwise terminates (e.g., due to time constraints or to the loss asymptotically approaching a lower bound). At this point, model 1210 is considered trained. Some embodiments may evaluate a performance of model 1210 based on testing data (e.g., data 1220 which was not used to train model 1210) and re-train model 1210 differently (e.g., using different initialization, etc.) if the performance is not satisfactory. As the model 1210 is used in the field, the model 1210 may be updated with different values and detected entity characteristics to update the model 1210.

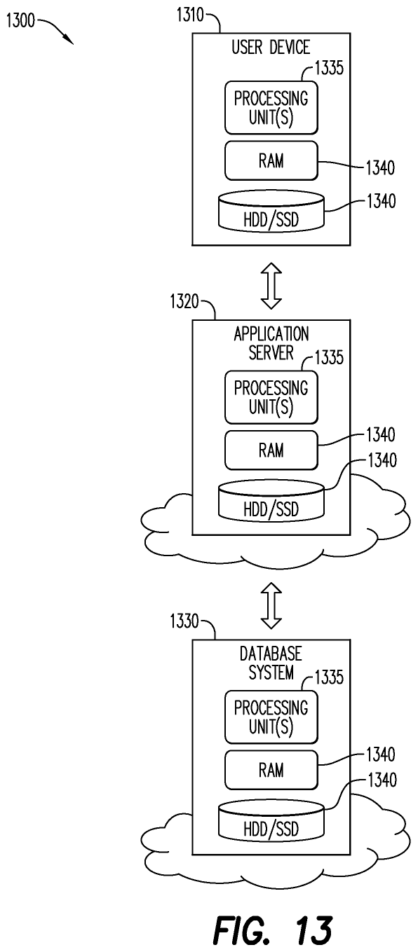

FIG. 13 illustrates a cloud-based database deployment 1300 according to some embodiments. The illustrated components may reside in one or more public clouds providing self-service and immediate provisioning, autoscaling, security, compliance and identity management features.

User device 1310 may interact with applications executing on the application server 1320 (cloud or on-premise), for example via a Web Browser executing on user device 1310, in order to create, read, update and delete data managed by database system 1330. Database system 1330 may store data as described herein and may execute processes as described herein to cause the execution of the selection module 104 for use with the user device 1310. Application server 1320 and database system 1330 may comprise cloud-based compute resources, such as virtual machines, allocated by a public cloud entity. As such, application server 1320 and database system 1330 may be subjected to demand-based resource elasticity. Each of the user device 1310, application server 1320, and database system 1330 may include a processing unit 1335 that may include one or more processing devices each including one or more processing cores. In some examples, the processing unit 1335 is a multicore processor or a plurality of multicore processors. Also, the processing unit 1335 may be fixed or it may be reconfigurable. The processing unit 1335 may control the components of any of the user device 1310, application server 1320, and database system 1330. The storage devices 1340 may not be limited to a particular storage device and may include any known memory device such as RAM, ROM, hard disk, and the like, and may or may not be included within a database system, a cloud environment, a web server or the like. The storage 1340 may store software modules or other instructions/executable code which can be executed by the processing unit 1335 to perform the method shown in FIG. 2. According to various embodiments, the storage device 1340 may include a data store having a plurality of tables, records, partitions and sub-partitions. The storage device 1340 may be used to store database records, documents, entries, and the like.

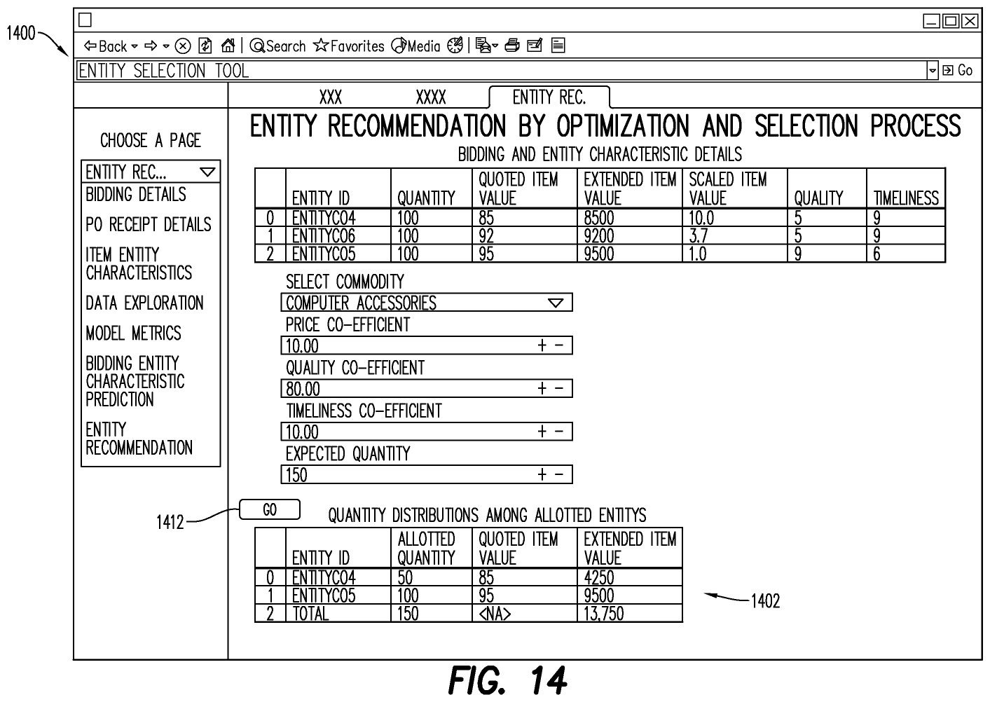

FIG. 14 provides the Entity Recommendation by Optimization and Selection User Interface display 1400 with another non-exhaustive example. Here, the Expected Quantity is 150, and quality is the most important as more weightage is given to quality than the others. Here, the event-target derived constraints expression/s is/are: SUBJECT TO: Constraint 1: EntityCO4+EntityCO5+EntityCO6=150 The weights are price=10, quality=80, and timeliness=10. The price expression is: 10.0*EntityC04+EntityC05+3.7*EntityC06; the quality expression is 5.0*EntityC04+9.0*EntityC05+5.0*EntityC06; and the timeliness expression is 9.0*EntityC04+6.0*EntityC05+9.0*EntityC06. The combined expression, as in FIG. 9, is: (weightage_price*priceExpression)+(weightage_quality*qualityExpression)+(weightage_timeliness*timelinessExpression)→(10*priceExpression)+(80*qualityExpression)+(10*timelinessExpression)→((10*10EntityCO4)+(10*1EntityCO5)+(10*3.7EntityCO6))+((80*5EntityCO4)+(80*1EntityCO5)+(80*5EntityCO6))+((10*9EntityCO4)+(10*6EntityCO5)+(10*9EntityCO6)→((100EntityCO4+10EntityCO5+37 EntityCO6)+(400EntityCO4+720EntityCO5+400EntityCO6)+(90EntityCO4+60EntityCO5+90EntityCO6)→sum for each entity→(100+400+90)EntityCO4+(10+720+60)EntityCO5+(37+4000+90)EntityCO6→590EntityCO4+790EntityCO5+527EntityCO6. The entity optimization is to maximize 590.0*EntityC04+790.0*EntityC05+527.0*EntityC06, with variables for each of EntityC04, EntityC05 and EntityC06 being greater than or equal to 0 and less than or equal to 100. It is noted that the optimization expression in FIG. 14 is different than the optimization expression in FIG. 9 because the weightages/coefficients have changed. Selection of the “Go” icon 612 executed the simulation and resulted in the table 1402 shown herein, including a recommended quantity distribution allotted among entities. In this non-exhaustive example, the optimization engine 114 recommends the expected quantity be allotted among multiple entities. In particular the optimization engine 114 recommends EntityC04 provide 50 and EntityC05 provide 100.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer-readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, external drive, semiconductor memory such as read-only memory (ROM), random-access memory (RAM), and/or any other non-transitory transmitting and/or receiving medium such as the Internet, cloud storage, the Internet of Things (IoT), or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

What is claimed is:

1. A system comprising:
a memory storing processor-executable program code; and
a processing unit to execute the processor-executable program code to:
train a machine learning model with prior values of characteristic parameters for a plurality of entities;
create an event, the event including an item value for a given quantity of an item provided by each of the plurality of entities;
receive an event target;
extract, via a name entity recognition model, an entity identifier from the event target for each entity in the event, wherein the entity identifier is in a first format;
convert the entity identifier from the first format to a second format;
generate one or more simulations based on a plurality of characteristic parameter constraints and the event target;
generate, for the item for each entity of the plurality of entities, a characteristic parameter value for each of the plurality of characteristic parameters via execution of the trained machine learning model;
scale the generated characteristic parameter values to a common unit of measure;
generate an output via execution of an optimization engine applied to each simulation with the scaled characteristic parameter values, wherein the output includes a quantity distribution of the given quantity to at least one of the plurality of entities; and
automatically trigger one or more processes in response to the generated output.

2. The system of claim 1, wherein the second format is a Java Script Object Notation (JSON).

3. The system of claim 1, further comprising processor-executable program code to:
train the machine learning model prior to creation of the event.

4. The system of claim 2, wherein at least one of the automatically triggered one or more processes is an update of the machine learning model.

5. The system of claim 1, wherein the characteristic parameter values comprise at least one of: an item value, a time value, and a quality value.

6. The system of claim 5, wherein the time value is based on prior provision of the item.

7. The system of claim 5, wherein the quality value is based on prior items accepted and prior items rejected.

8. The system of claim 1, wherein the characteristic parameter constraints for each simulation comprise at least one of: an item value co-efficient, a quality co-efficient, and a time co-efficient.

9. The system of claim 8, wherein each characteristic parameter constraint is one of received with the event target and default values.

10. The system of claim 9, further comprising processor-executable program code to:
generate, via the optimization engine, a plurality of linear programming expressions comprising a linear programming expression for a scaled characteristic parameter for each scaled characteristic parameter value.

11. The system of claim 10, further comprising processor-executable program code to:
generate an updated linear programming expression by injecting one or more variables to the generated linear programming expression in a case the optimization engine outputs “infeasible” in execution of linear programming expression; and
determine a feasibility for the updated linear programming expression.

12. A computerized method comprising:
training a machine learning model with prior values of characteristic parameters for a plurality of entities;
creating an event, the event including an item value for a given quantity of an item provided by each of the plurality of entities, wherein the event is created after the machine learning model is trained;
receiving an event target;
extracting, via a name entity recognition model, an entity identifier from the event target for each entity in the event, wherein the entity identifier is in a first format;
converting the entity identifier from the first format to a second format;
generating one or more simulations based on a plurality of characteristic parameter constraints and the event target;
generating, for the item for each entity of the plurality of entities, a characteristic parameter value for each of the plurality of characteristic parameters via execution of the trained machine learning model;
scaling the generated characteristic parameter values to a common unit of measure;
generating an output via execution of an optimization engine applied to each simulation with the scaled characteristic parameter values, wherein the output includes a quantity distribution of the given quantity to at least one of the plurality of entities; and
automatically triggering one or more processes in response to the generated output.

13. The method of claim 12, wherein the second format is a Java Script Object Notation.

14. The method of claim 12, wherein at least one of the automatically triggered one or more processes is an update of the machine learning model.

15. The method of claim 12, wherein the characteristic parameter values comprise at least one of: an item value, a time value, and a quality value.

16. The method of claim 12, wherein the characteristic parameter constraints for each simulation comprise at least one of: an item value co-efficient, a quality co-efficient, and a time co-efficient.

17. The method of claim 16, further comprising:
generating, via an optimization engine, a plurality of linear programming expressions comprising a linear programming expression for a scaled characteristic parameter for each scaled characteristic parameter value.

18. The method of claim 17, further comprising:
generating an updated linear programming expression by injecting one or more variables to the generated linear programming expression in a case an optimization engine outputs “infeasible” in execution of the linear programming expression; and
determining a feasibility for the updated linear programming expression.

19. A non-transitory computer readable medium having executable instructions stored therein to perform a method, the method comprising:
training a machine learning model with prior values of characteristic parameters for a plurality of entities;
creating an event, the event including an item value for a given quantity of an item provided by each of the plurality of entities;
receiving an event target;
extracting, via a name entity recognition model, an entity identifier from the event target for each entity in the event, wherein the entity identifier is in a first format;
converting the entity identifier from the first format to a second format;
generating one or more simulations based on a plurality of characteristic parameter constraints and the event target;
generating, for the item for each entity of the plurality of entities, a characteristic parameter value for each of the plurality of characteristic parameters via execution of the trained machine learning model, wherein the characteristic parameter values comprise at least one of: an item value, a time value, and a quality value;
scaling the generated characteristic parameter values to a common unit of measure;
generating an output via execution of an optimization engine applied to each simulation with the scaled characteristic parameter values, wherein the output includes a quantity distribution of the given quantity to at least one of the plurality of entities; and
automatically triggering one or more processes in response to the generated output.

20. The medium of claim 19 further comprising:
generating, via an optimization engine, a plurality of linear programming expressions comprising a linear programming expression for a scaled characteristic parameter for each scaled characteristic parameter value;
generating an updated linear programming expression by injecting one or more variables to the generated linear programming expression in a case an optimization engine outputs “infeasible” in execution of the linear programming expression; and
determining a feasibility for the updated linear programming expression.
